(19) United States
(12) Patent Application Publication
(10) Pub. No.: US 2012/0288355 A1
(43) Pub. Date: Nov. 15, 2012

(54) Method for storing wafers

(76) Inventors: Ming-Teng Hsieh, New Taipei City (TW); Yi-Nan Chen, Taipei City (TW); Hsien-Wen Liu, Taoyuan County (TW)

(21) Appl. No.: 13/105,881

(22) Filed: May 11, 2011

(51) Int. Cl. H01L 21/677; B65B 31/00

(52) U.S. Cl. 414/805; 414/800; 53/405

(57) ABSTRACT

A method for storing wafers is disclosed. A plurality of wafers are placed into the wafer cassette box. The wafer cassette box is hermetically sealed and pumped down to vacuum for the wafer storage. Alternatively, the wafers carried by a holder conveyed on a wafer conveyor are placed into a pump-down chamber enclosing a section of the wafer conveyor. The pump-down chamber is hermetic sealed and pumped down to vacuum for the wafer storage on the wafer conveyor.

### BACKGROUND OF THE INVENTION

1. Field of the Invention

The present invention relates to a method of fabricating semiconductor devices, and particularly to a method of storing wafers in the interval of two semiconductor manufacturing processes.

2. Description of the Prior Art

In the semiconductor fabrication technology, extremely high cleanliness environment is demanded for wafer processing. The wafers for processing and loading/unloading to/from a process tool are constantly flushed with ultra-pure nitrogen that contains no oxygen and moisture, in order to eliminate micro-contamination and to reduce native oxide growth on silicon surfaces. During a Q-time between two fabricating processes, as shown in FIG. 1, wafers 2 are usually stored in a wafer storage container 4 without the particle contamination, moisture absorption and oxidation problems by maintaining a positive pressure of an inert gas (such as nitrogen gas) inside the container higher than the surrounding environment outside the container. The wafers are transported (also referred to as “conveyed”) from one process tool or apparatus to another.

However, the ultra-pure nitrogen gas is costly. Therefore, there is still a need for a novel method for storing wafers efficiently and economically.

### SUMMARY OF THE INVENTION

One object of the present invention is to provide a method for storing wafers to prolong Q time.

According to one embodiment of the present invention, a method for storing wafers includes steps as follows. A wafer cassette box is provided. A plurality of wafers are placed into the wafer cassette box. The wafer cassette box is hermetically sealed. The wafer cassette box having the wafers therein is pumped down to vacuum. Accordingly, the wafers can be stored in the wafer cassette box in vacuum.

According to another embodiment of the present invention, a method for storing wafers on a wafer conveyor includes steps as follows. A wafer conveyor is provided. A pump-down chamber is formed to enclose a section of the wafer conveyor. A plurality of wafers carried by a holder are conveyed on the wafer conveyor into the pump-down chamber. The pump-down chamber is sealed. The pump-down chamber is pumped down to vacuum. Accordingly, the wafers can be stored as being carried by the holder on the wafer conveyor in the pump-down chamber in vacuum.

According to further another embodiment of the present invention, a method for storing wafers on a wafer conveyor includes steps as follows. A wafer conveyor is provided. A pump-down chamber is formed to enclose a first section of the wafer conveyor. The pump-down chamber is pumped down to vacuum. A pre-pump chamber is formed to enclose a second section of the wafer conveyor adjacent to a first side of the pump-down chamber. A plurality of wafers carried by a holder is conveyed on the wafer conveyor into the pre-pump chamber. The pre-pump chamber is pumped down to a reduced air pressure. The wafers with the holder together are conveyed from the pre-pump chamber into the pump-down chamber. The pump-down chamber is pumped down with the wafers therein to vacuum for storing the wafers.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a conventional method to store wafers in a wafer cassette box;

FIG. 2 is a flowchart illustrating an embodiment of the method for storing wafers according to the present invention;

FIG. 3 is a schematic diagram illustrating an embodiment of the method for storing wafers according to the present invention;

FIGS. 4 and 5 are flow charts illustrating some embodiments of the method for storing wafers on a wafer conveyor according to the present invention; and

FIGS. 6 and 7 are schematic diagrams illustrating some embodiments of the method for storing wafers on a wafer conveyor according to the present invention.

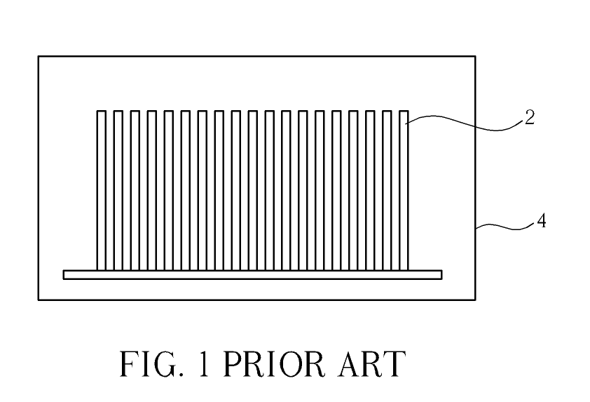

### DETAILED DESCRIPTION

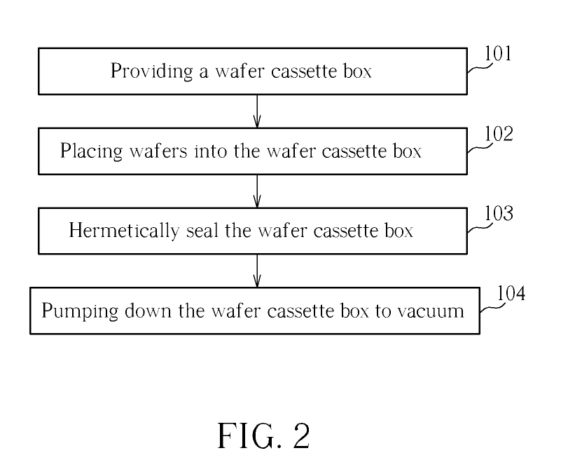

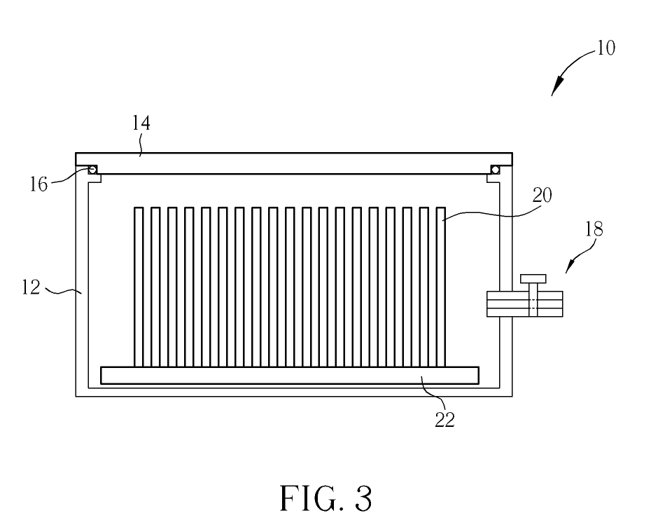

Referring to FIG. 2 and FIG. 3, a method for storing wafers according to an embodiment includes steps described as follows. First, Step 101 is performed to provide a wafer cassette box. The wafer cassette box 10 may include a box body 12 having an opening and a cover member 14 for closing the opening. The wafer cassette box 10 may be a conventional one. The cover member 14 can be used to hermetically cover the opening to allow the wafer cassette box 10 to be in an airtight status. The wafer cassette box 10 has a valve 18 for pumping. The valve 18 may be disposed on the box body 12 or the cover member 14.

Next, Step 102 is performed to place wafers 20 into the wafer cassette box 10 through the opening of the wafer cassette box 10. The wafers 20 may be semi-products processed from a semiconductor device manufacturing process and wait for a subsequent process. The wafers 20 may be usually carried by a holder 22. The wafers 20 and the holder 22 may be put together into the wafer cassette box 10 for storage until being fetched out for the subsequent process. The Step 103 is performed to hermetically seal the wafer cassette box 10. In this embodiment, sealing the wafer cassette box 10 maybe accomplished by covering the opening with the cover member 14. An o-ring 16 may be further disposed to surround the opening or the cover member, such that when the cover member covers the opening, the o-ring 16 can be between the cover member and the opening to hermetically seal the wafer cassette box 10.

Thereafter, Step 104 is performed to pump down the wafer cassette box 10 to vacuum. The pumping may be through the valve 18. The valve 18 may be a one-direction valve for only permit one-way airflow, or a two- or more-direction valve which can be turned off for prohibiting the air from flowing into the wafer cassette box 10 through the valve after the vacuum status is reached. A useful vacuum pump is not particularly limited as long as it can achieve the desired vacuum and does not cause pollution. After the vacuum status is reached and the valve is turned off, the wafers are in a wafer cassette box and separated from environmental air for storage.

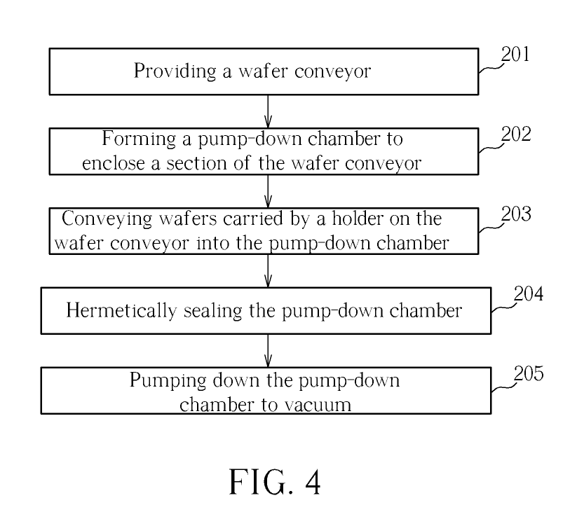

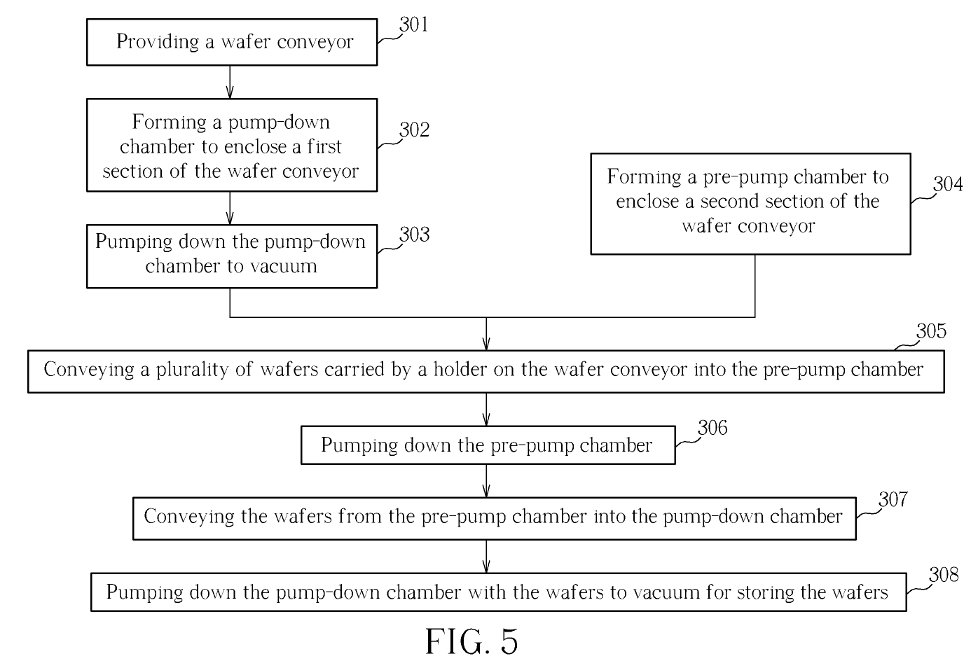

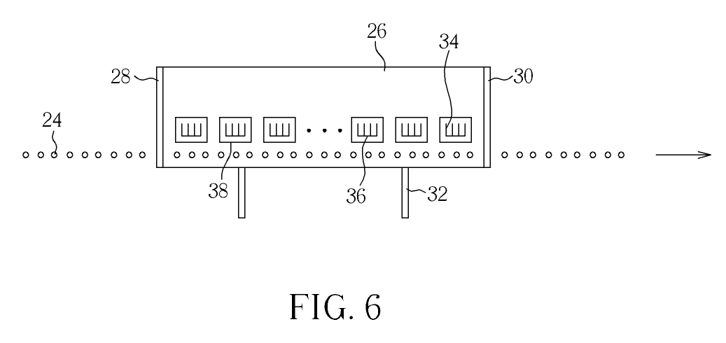

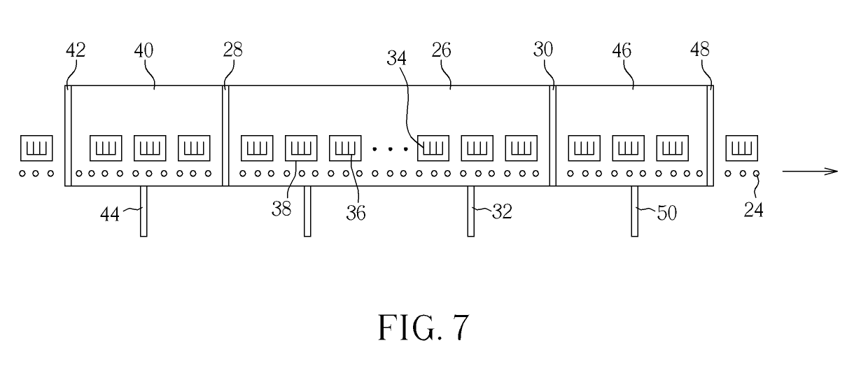

FIGS. 4 and 5 further illustrate flow charts according to some other embodiments. FIGS. 6 and 7 are schematic diagrams for illustrating the embodiments. According to the embodiments, the wafers are stored in a holder on a wafer conveyor. The holder may be a cassette for carrying the wafers to process tools or apparatus. The wafer conveyor is for conveying the wafers carried by the cassette to process tools or apparatus. In the embodiments of the present invention, the wafers carried by the holder are stored on the wafer conveyor, such that loading and unloading procedures may be not needed. Accordingly, it is time saving and convenient.

Referring to FIG. 4 and FIG. 6, a method for storing wafers on a wafer conveyor according to the embodiment includes steps described as follows. First, Step 201 is performed to provide a wafer conveyor 24. The wafer conveyor is preferably a roller conveyor. Next, Step 202 is performed to form a pump-down chamber 26 to enclose a section of the wafer conveyor 24. The pump-down chamber 26 may include an inlet with a door 28 and an outlet with a door 30 to allow the wafer conveyor 24 to go through the pump-down chamber 26. The pump-down chamber 26 further includes at least one valve 32 for pumping down the pump-down chamber 26 to vacuum. The valve 32 may be as aforesaid. Thereafter, Step 203 is performed to convey the wafers 34 carried by a holder 36 on the wafer conveyor 24 into the pump-down chamber 26 from, for example, the inlet. The wafers 34 and the holder 36 may be placed within a box 38, such as a SMIF (standard mechanical interface) pod. Step 204 is performed to hermetically seal the pump-down chamber 26, which may be achieved by closing the doors 28 and 30. Preferably, an o-ring is disposed between each of the doors and each of the openings of the inlet and the outlet for securing the airtight status. Step 205 is performed to pump down the pump-down chamber 26 to vacuum, and accordingly the wafers 34 are stored in the pump-down chamber 26 on the wafer conveyor 24.

Referring to FIG. 5 and FIG. 7, a method for storing wafers on a wafer conveyor according to the embodiment includes steps described as follows, in which a pre-pump down step is performed. First, Step 301 is performed to provide a wafer conveyor 24. The wafer conveyor is preferably a roller conveyor. Next, Step 302 is performed to forming a pump-down chamber 26 to enclose a first section of the wafer conveyor 24. The pump-down chamber 26 may be as aforesaid. Thereafter, Step 303 is performed to pump down the pump-down chamber 26 to vacuum.

Not limited to the time order with respect to Steps 301 to 303, Step 304 is performed to form a pre-pump chamber 40 to enclose a second section of the wafer conveyor 24. The pre-pump chamber 40 is disposed adjacent to a side of the pump-down chamber 26 and may also include an inlet with a door and an outlet with a door to allow the wafer conveyor 24 to go through. The outlet with the door may be merged with the inlet with the door 28 of the pump-down chamber 26 to be one, as shown in FIG. 7. The pre-pump chamber 40 may further include at least one valve 44 for pumping. Preferably, an o-ring is disposed between each of the doors and each of the openings of the inlet and the outlet for securing the airtight status.

Step 305 is performed to convey the wafers 34 carried on the holder 36 on the wafer conveyor 24 into the pre-pump chamber 40. Step 306 is performed to pump down the pre-pump chamber 40 to a reduced air pressure through the valve 44, with the doors closed. This step allows the wafers not to suffer from a drastic change of air pressure in the moment when the door 28 is opened. Accordingly, the reduced air pressure may be less than that in the environment and greater than that in the pump-down chamber 26. Step 307 is performed to convey the wafers 34 carried by the holder 36 on the wafer conveyor 24 from the pre-pump chamber 40 into the pump-down chamber 26. Step 308 is performed to pump down the pump-down chamber 26 with the wafers 34 therein through the valve 32, preferably with the doors 28 and 30 closed, to vacuum for storing the wafers 34. Thereafter, the valve 32 is turned off if it is desired. Accordingly, the wafers 34 can be stored on the wafer conveyor 24 for waiting for the subsequent process.

Furthermore, referring to FIG. 7, an open-pump chamber 46 may be further formed to enclose a third section of the wafer conveyor 24 adjacent to another side of the pump-down chamber 26. The open-pump chamber 46 may include an inlet with a door and an outlet with a door 48 to allow the wafer conveyor 24 to go through. The inlet with the door may be merged with the outlet with the door 30 of the pump-down chamber 26 to be one, as shown in FIG. 7. The open-pump chamber 46 may further include at least one valve 50 for pumping. Preferably, an o-ring is disposed between each of the doors and each of openings of the inlet and the outlet for securing the airtight status. When the wafers are about to be conveyed to a subsequent processing tool or apparatus, the open-pump chamber 46 may be pumped down through the valve 50 to a reduced air pressure, such that the wafers 34 will not suffer from a drastic change of air pressure in the moment when the door 30 is opened. Accordingly, the reduced air pressure may be less than that in the environment and greater than that in the pump-down chamber 26. Thereafter, the wafers 34 are conveyed from the pump-down chamber 26 into the open-pump chamber 46. Thereafter, the wafers 34 are conveyed out of the open-pump chamber 46.

In the present invention, when the wafers are stored in vacuum, the wafers are separated from contaminates, such as oxygen gas, moisture, and particles. Accordingly, inert gas, such as nitrogen, is not required to purge or fill the wafer cassette box, to reduce production cost.

Those skilled in the art will readily observe that numerous modifications and alterations of the device and method may be made while retaining the teachings of the invention.

What is claimed is:

1. A method for storing wafers, comprising:
providing a wafer cassette box;
placing a plurality of wafers into the wafer cassette box;
hermetically sealing the wafer cassette box; and
pumping down the wafer cassette box having the wafers therein to vacuum.

2. The method for storing wafers according to claim 1, wherein, the wafer cassette box comprises a box body having an opening, a cover member for hermetically covering the opening, and a valve disposed on the box body or the cover member for pumping down the wafer cassette box to vacuum.

3. The method for storing wafers according to claim 2, wherein an o-ring is disposed to surround the opening for the cover member to hermetically cover the opening.

4. The method for storing wafers according to claim 2, wherein an o-ring is disposed to surround the cover member for the cover member to hermetically cover the opening.

5. A method for storing wafers on a wafer conveyor, comprising:
providing a wafer conveyor;
forming a pump-down chamber to enclose a section of the wafer conveyor;
conveying a plurality of wafers carried by a holder on the wafer conveyor into the pump-down chamber;
hermetically sealing the pump-down chamber; and
pumping down the pump-down chamber to vacuum.

6. The method for storing wafers on a wafer conveyor according to claim 5, wherein, the pump-down chamber comprises an inlet with a first door and an outlet with a second door to allow the wafer conveyor to go through the pump-down chamber, and a valve for pumping down the pump-down chamber to vacuum, and
the step of hermetically sealing the pump-down chamber comprises hermetically closing the first door and the second door.

7. The method for storing wafers on a wafer conveyor according to claim 6, wherein an o-ring is disposed to surround each of the inlet and the outlet respectively for hermetically closing the first and the second doors.

8. The method for storing wafers on a wafer conveyor according to claim 6, wherein an o-ring is disposed to surround each of the first and the second doors for hermetically closing the first and the second doors.

9. A method for storing wafers on a wafer conveyor, comprising:
providing a wafer conveyor;
forming a pump-down chamber to enclose a first section of the wafer conveyor;
pumping down the pump-down chamber to vacuum;
forming a pre-pump chamber to enclose a second section of the wafer conveyor adjacent to a first side of the pump-down chamber;
conveying a plurality of wafers carried by a holder on the wafer conveyor into the pre-pump chamber;
pumping down the pre-pump chamber to a reduced air pressure;
conveying the wafers from the pre-pump chamber into the pump-down chamber; and
pumping down the pump-down chamber with the wafers therein to vacuum for storing the wafers.

10. The method for storing wafers on a wafer conveyor according to claim 9, further comprises:
forming an open-pump chamber to enclose a third section of the wafer conveyor adjacent to a second side of the pump-down chamber;
pumping down the open-pump chamber to a reduced air pressure;
conveying the wafers from the pump-down chamber into the open-pump chamber; and
conveying the wafers out of the open-pump chamber.
